(19) United States
(12) Patent Application Publication
(10) Pub. No.: US 2026/0091369 A1
(43) Pub. Date: Apr. 2, 2026

(54) PREPARATION METHOD AND USE OF AMINE-FUNCTIONALIZED ADSORPTION MATERIAL WITH HIGHLY DISPERSED ACTIVE SITES

(71) Applicant: ZHEJIANG UNIVERSITY OF TECHNOLOGY, Hangzhou (CN)

(72) Inventors: Shihan ZHANG, Hangzhou (CN); Yao SHEN, Hangzhou (CN); Wenyuan JIN, Hangzhou (CN); Jingkai ZHAO, Hangzhou (CN); Beini ZHANG, Hangzhou (CN); Jiexu YE, Hangzhou (CN)

(73) Assignee: ZHEJIANG UNIVERSITY OF TECHNOLOGY, Hangzhou (CN)

(21) Appl. No.: 19/412,921

(22) Filed: Dec. 9, 2025

Related U.S. Application Data
(63) Continuation of application No. PCT/CN2024/132799, filed on Nov. 18, 2024.

(30) Foreign Application Priority Data
Feb. 5, 2024 (CN) 202410163155.0

(51) Int. Cl. B01J 20/32; B01D 53/62; B01D 53/81; B01J 20/20; B01J 20/22; B01J 20/30; C23C 16/02; C23C 16/50; C23C 16/56

(52) U.S. Cl. CPC B01J 20/3248; B01D 53/62; B01D 53/81; B01J 20/20; B01J 20/22; B01J 20/3078; B01J 20/3204; B01J 20/3217; C23C 16/0218; C23C 16/50; C23C 16/56; B01D 2253/102; B01D 2253/20; B01D 2253/25; B01D 2257/504

(57) ABSTRACT

A preparation method and use of an amine-functionalized adsorption material with highly dispersed active sites are provided. The preparation method includes: placing a graphene aerogel (GA) in a tube furnace, and conducting a thermal reduction treatment; placing a thermally reduced sample in a plasma vapor deposition tube, and subjecting the sample to a plasma treatment in different atmospheres under vacuum to produce a carrier; drying the carrier overnight; adding a polyamino organic amine and the carrier to a reactor, and heating in a forced air oven; taking a reaction product out, and removing an organic amine adhering to a surface of the reaction product; soaking in ethanol, and drying overnight in the forced air oven to produce the amine-functionalized adsorption material with highly dispersed active sites.

### CROSS REFERENCE TO THE RELATED APPLICATIONS

This application is a continuation application of International Application No. PCT/CN2024/132799, filed on Nov. 18, 2024, which is based upon and claims priority to Chinese Patent Application No. 202410163155.0, filed on Feb. 5, 2024, the entire contents of which are incorporated herein by reference.

### TECHNICAL FIELD

The present disclosure belongs to the field of preparation of functionalized materials, and specifically relates to a preparation method and use of an amine-functionalized adsorption material with highly dispersed active sites.

### BACKGROUND

In recent years, dual-carbon goals have attracted widespread attention globally. Accordingly, “carbon peaking” and “carbon neutrality” have become popular internet terms. The reason behind this phenomenon is precisely that the massive emission of carbon dioxide by humans causes global warming and leads to a series of disasters such as rising sea levels, ozone layer depletion, ocean acidification, and unpredictable weather conditions, which endanger human lives. Therefore, controlling carbon dioxide emissions and capturing carbon dioxide have become urgent tasks.

Post-combustion CO₂ capture technologies are readily implementable in practical applications. Adsorption methods currently receive significant attention as post-combustion CO₂ treatment techniques. According to adsorption strengths, the adsorption methods can be classified into physical adsorption and chemical adsorption. The physical adsorption exhibits relatively weak adsorption interactions, resulting in low regeneration energy consumption and poor selectivity. The chemical adsorption demonstrates strong adsorption interactions and specific selectivity, and enables the highly selective adsorption of a specified substance. However, the chemical adsorption involves relatively high energy consumption for regeneration. Currently, amine-functionalized adsorption materials are widely used as adsorbents due to high CO₂ adsorption capacity. The adsorption of CO₂ by amine-functionalized adsorption materials primarily follows the zwitterion mechanism, but there are still some specific factors affecting this adsorption mechanism. For example, in the absence of an additional proton acceptor, a proton of a zwitterion can only be transferred to an adjacent amine functional group, resulting in the failure of CO₂ adsorption. In this case, two adsorption sites are required to capture one CO₂ molecule. In the presence of an additional proton acceptor (particularly a proton acceptor with a higher proton acceptance capacity than an amine functional group), a zwitterion transfers a proton preferentially to this proton acceptor to enable the ideal scenario where one adsorption site captures one CO₂ molecule, which significantly improves the utilization efficiency of amine groups. Amine-functionalized adsorption materials can achieve a high CO₂ adsorption capacity by loading a specified amount of an organic amine. However, organic amines are prone to agglomeration, leading to pore blockage in substrate materials.

In the present disclosure, numerous point defects are created in an amine-functionalized adsorption material, and an organic amine is combined with these point defects. As a result, an amine load can be flexibly adjusted, and amine molecules can be highly dispersed, which effectively mitigates the issue of organic amine agglomeration. Moreover, an additional proton acceptor is introduced to enhance proton transfer, thereby improving the adsorption performance of the adsorption material.

### SUMMARY

In view of limitations of the prior art, the present disclosure provides a preparation method and use of an amine-functionalized adsorption material with highly dispersed active sites. The preparation method includes the following steps:
(1) placing 10 mg to 30 mg of a graphene aerogel (GA) in a corundum tube of a tube furnace, and conducting a thermal reduction treatment to produce a thermally reduced sample;
(2) placing 10 mg to 30 mg of the sample obtained in the step (1) in a plasma vapor deposition tube, and subjecting the sample to a plasma treatment in different atmospheres under vacuum at an absolute pressure of less than 30 kPa to produce a carrier for later use; and
(3) drying the carrier obtained in the step (2) overnight; adding 10 mL to 50 mL of organic amines and 10 mg to 30 mg of the carrier to a reactor, and heating in a forced air oven at 60° C. to 100° C. for 8 h to 15 h; taking a reaction product out, and removing an organic amine adhering to a surface of the reaction product using an absorbent paper; soaking in 150 mL to 200 mL of absolute ethanol for 10 min to 40 min, and drying overnight in the forced air oven at 60° C. to 100° C. to produce the amine-functionalized adsorption material with highly dispersed active sites.

Further, in the step (1), the thermal reduction treatment includes: conducting 2 to 3 vacuuming-argon purging cycles to remove oxygen from the corundum tube, heating at a heating rate of 8° C./min to 12° C./min (preferably 10° C./min) to a temperature of 1,200° C. to 1,600° C. under protection of argon at a flow rate of 10 mL/min to 20 mL/min, maintaining the temperature for 2 h to 3 h, and cooling naturally.

Further, in the step (2), the atmosphere for the plasma treatment includes argon, helium, hydrogen, or carbon monoxide.

Further, in the step (2), the plasma treatment includes: conducting 2 to 3 vacuuming cycles to remove oxygen from the plasma vapor deposition tube, heating at a heating rate of 8° C./min to 12° C./min (preferably 10° C./min) to a temperature of 600° C. to 900° C. under protection of different atmospheres at a flow rate of 10 mL/min to 20 mL/min, setting a plasma power to 200 W, and conducting the plasma treatment for 1 min to 180 min.

Further, in the step (3), the polyamino organic amine includes triethylenetetramine (TETA), tetraethylenepentamine (TEPA), or N,N′-dimethylethylenediamine (MMEN).

Further, in the step (3), the drying in the oven is conducted at 60° C. to 90° C.

Further, in the step (3), the soaking in the absolute ethanol is conducted at 30° C. to 50° C.

The present disclosure also provides a study on an amine load in the amine-functionalized adsorption material with highly dispersed active sites.

Compared with the prior art, the present disclosure has the following beneficial effects: The amine-functionalized adsorption material with highly dispersed active sites in the present disclosure is produced by creating numerous point defects on a carbon material through thermal reduction and plasma treatments and grafting different organic amines. The key lies in the plasma treatment that creates a sufficient number of point defects to uniformly disperse amine molecules, which prevents the agglomeration of organic amines. Thus, an amine load can be flexibly regulated, and amine molecules can be highly dispersed. Moreover, an additional proton acceptor is introduced to enhance proton transfer, thereby improving the adsorption performance of the adsorption material.

### BRIEF DESCRIPTION OF THE DRAWINGS

FIG. 1 shows aberration-corrected electron microscopy images of GA before and after a plasma treatment in the present disclosure;

FIG. 2 shows X-ray photoelectron spectroscopy (XPS) full-spectrum analysis results for dGA and TEPA-dGA in the present disclosure;

FIG. 3 shows Raman mapping (ID/IG) results for reduced graphene aerogel (rGA), defective graphene aerogel (dGA), and TEPA-dGA in the present disclosure; and

FIG. 4 shows high-resolution N1s spectrum analysis results for dGA and TEPA-dGA in the present disclosure.

### DETAILED DESCRIPTION OF THE EMBODIMENTS

The technical solutions of the present disclosure are further described below in conjunction with the accompanying drawings and embodiments.

The GA used in these embodiments was prepared through the following process:
(1) A graphene oxide aqueous dispersion (12.55 mg/g) and ultrapure water were mixed at a volume ratio of 1:1 and stirred for 10 min to produce a uniform diluted solution with a concentration of 6.275 mg/g.
(2) 16 g of the diluted solution was taken and spread evenly on a plastic Petri dish with a diameter of 60 mm, and then dried in a 60° C. oven for 6 h to produce a graphene oxide sheet.
(3) The graphene oxide sheet was soaked in a 30 vol % hydrazine hydrate solution at room temperature to allow foaming for 3 h, such that the graphene oxide sheet gradually expanded into a foam-like structure.
(4) A foamed product was completely immersed in 20 mL of absolute ethanol for 3 h. The complete immersion was repeated three times. The original absolute ethanol was replaced with fresh absolute ethanol each time. The complete immersion was conducted once with n-hexane instead of the absolute ethanol. Drying was conducted overnight in a 60° C. oven to produce the GA.

### Example 1

The present disclosure provided a preparation method of TEPA-modified GA, including the following specific steps:
(1) 20 mg of the GA was placed in a corundum tube of a tube furnace, and subjected to a thermal reduction treatment (3 vacuuming-argon purging cycles were conducted to remove oxygen from the corundum tube, and the GA was heated at a heating rate of 10° C./min to a temperature of 1,400° C. under protection of argon at a flow rate of 15 mL/min, kept at the temperature for 2.5 h, and then naturally cooled to an ambient temperature) to produce rGA.
(2) 20 mg of the rGA obtained in the step (1) was placed in a plasma vapor deposition tube, and subjected to a plasma treatment in an argon atmosphere under vacuum at an absolute pressure of less than 30 kPa (2 vacuuming cycles were conducted to remove oxygen from the plasma vapor deposition tube, heating was conducted at a heating rate of 10° C./min to a temperature of 750° C. under protection of the argon atmosphere at a flow rate of 15 mL/min, a plasma power was set to 200 W, and the plasma treatment was conducted for 90 min) to produce dGA.
(3) The dGA obtained in the step (2) was dried overnight for 12 h to produce dried dGA. 25 mL of pure TEPA and 20 mg of the dried dGA were added to a reactor, and heated in a forced air oven at 90° C. for 10 h. A reaction product was taken out, and an organic amine adhering to a surface of the reaction product was gently removed using an absorbent paper. A resulting sample was soaked in 170 mL of absolute ethanol at 40° C. for 20 min, and dried at 80° C. overnight for 12 h to produce an adsorption material TEPA-dGA.

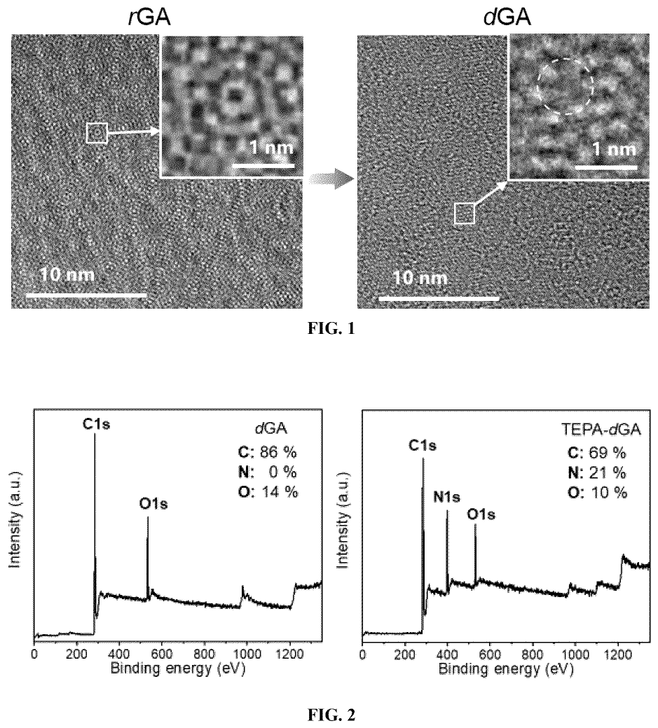

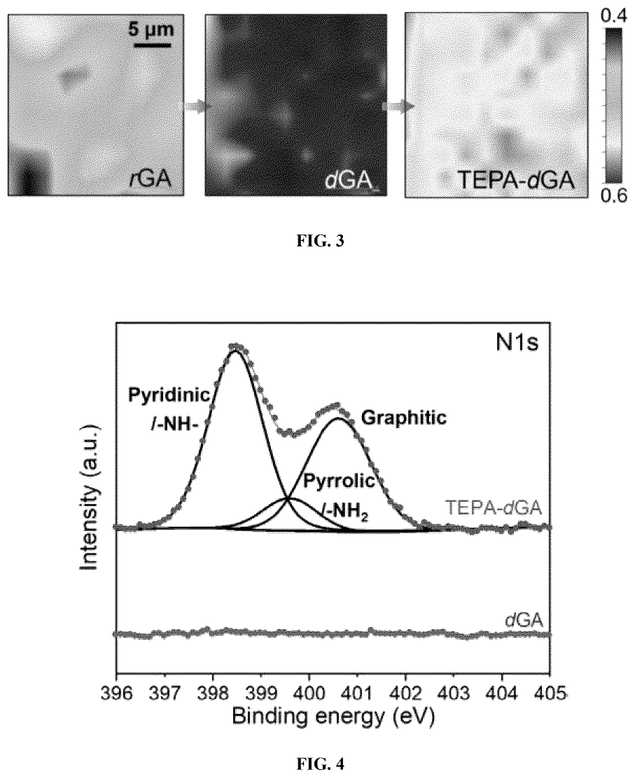

Aberration-corrected electron microscopy images and XPS full spectra of GAs prepared in this example are shown in FIG. 1 and FIG. 2, respectively. After the plasma treatment in the argon atmosphere, the regular diffraction pattern of rGA is disrupted, and a large number of point defects have been successfully introduced in dGA. Prior to TEPA modification, a surface of dGA has almost no nitrogen. A surface of TEPA-modified GA has a nitrogen content of 20%. FIG. 3 shows Raman mapping images of rGA, dGA, and TEPA-dGA. The overall Ip/IG value of rGA is 0.4 to 0.5. After the plasma bombardment in the argon atmosphere, the overall Ip/IG value of dGA significantly increases to 0.6, indicating the introduction of a large number of point defects uniformly distributed on a surface of dGA. After the TEPA modification, the overall Ip/IG value decreases to 0.55, indicating that TEPA can accurately and uniformly bind to the dispersed sites of point defects.

FIG. 4 shows high-resolution N1s spectra before and after TEPA modification. Nitrogen on a surface of TEPA-dGA primarily exists in three forms: pyridinic nitrogen, pyrrolic nitrogen, and graphitic nitrogen. TEPA molecules inherently exhibit characteristics of pyridinic and pyrrolic nitrogen in XPS analysis, and do not include graphitic nitrogen. Graphitic nitrogen is a configuration where one nitrogen atom is bonded with three carbon atoms. This specific nitrogen configuration can only be produced when an amino functional group of TEPA is covalently bonded with a point defect on the surface of dGA. Therefore, it is confirmed that TEPA-dGA is an amine-functionalized adsorption material with highly dispersed active sites.

An amine load of TEPA-dGA prepared in this example was investigated. A thermogravimetric analysis (TGA) curve of TEPA-dGA shows only one weight loss peak, indicating that the loaded amine is totally grafted on the material and there is no physically adsorbed organic amine. When the plasma treatment in the argon atmosphere is conducted for 1 min, 5 min, 15 min, 30 min, 60 min, and 180 min, the corresponding TEPA loads in TEPA-dGA are 16 wt %, 36 wt %, 44 wt %, 66 wt %, 74 wt %, and 87 wt %, respectively.

Density functional theory (DFT) calculations reveal that TEPA-dGA prepared in this example can achieve the chemical adsorption of CO₂ and the deprotonation simultaneously in a single step, which simplifies a reaction process and facilitates the deprotonation of zwitterions produced after the adsorption of CO₂ by an amine group. Thus, the CO₂ adsorption performance can be enhanced.

Further, the adsorption material prepared above can be subjected to amine group modulation. A duration of the plasma treatment in the argon atmosphere can be adjusted to achieve a TEPA load meeting a specific requirement. When the adsorption material is used for CO₂ adsorption, TEPA is prevented from agglomeration due to the binding of TEPA to a surface of the GA material in a highly dispersed manner, which can improve the adsorption performance. When the adsorption material is used in static adsorption under a 100% CO₂ condition for 30 min, a CO₂ adsorption capacity reaches 12 mmol/g, and an amine utilization efficiency is up to 90%.

### Example 2

The present disclosure provided a preparation method of TETA-modified GA, including the following specific steps:
(1) 30 mg of the GA was placed in a corundum tube of a tube furnace, and subjected to a thermal reduction treatment (2 vacuuming-argon purging cycles were conducted to remove oxygen from the corundum tube, and the GA was heated at a heating rate of 12° C./min to a temperature of 1,500° C. under protection of argon at a flow rate of 18 mL/min, kept at the temperature for 2 h, and then naturally cooled to an ambient temperature) to produce rGA.
(2) 25 mg of the rGA obtained in the step (1) was placed in a plasma vapor deposition tube, and subjected to a plasma treatment in an argon atmosphere under vacuum at an absolute pressure of less than 30 kPa (3 vacuuming cycles were conducted to remove oxygen from the plasma vapor deposition tube, heating was conducted at a heating rate of 8° C./min to a temperature of 650° C. under protection of the argon atmosphere at a flow rate of 10 mL/min, a plasma power was set to 200 W, and the plasma treatment was conducted for 150 min) to produce dGA.
(3) The dGA obtained in the step (2) was dried overnight for 11 h to produce dried dGA. 25 mL of pure TETA and 20 mg of the dried dGA were added to a reactor, and heated in a forced air oven at 90° C. for 10 h. A reaction product was taken out, and an organic amine adhering to a surface of the reaction product was gently removed using an absorbent paper. A resulting sample was soaked in 170 mL of absolute ethanol at 35° C. for 20 min, and dried at 80° C. overnight for 13 h to produce an adsorption material TETA-dGA.

TETA loads in TETA-dGA prepared in this example under different argon treatment durations are investigated, and the maximum TETA load is 54.0 wt %. When TETA-dGA is used in static adsorption of CO₂ under a 100% CO₂ condition for 30 min, a CO₂ adsorption capacity reaches 6 mmol/g.

### Example 3

The present disclosure provided a preparation method of MMEN-modified GA, including the following specific steps:
(1) 30 mg of the GA was placed in a corundum tube of a tube furnace, and subjected to a thermal reduction treatment (3 vacuuming-argon purging cycles were conducted to remove oxygen from the corundum tube, and the GA was heated at a heating rate of 8° C./min to a temperature of 1,300° C. under protection of argon at a flow rate of 12 mL/min, kept at the temperature for 2 h, and then naturally cooled to an ambient temperature) to produce rGA.
(2) 25 mg of the rGA obtained in the step (1) was placed in a plasma vapor deposition tube, and subjected to a plasma treatment in a hydrogen atmosphere under vacuum at an absolute pressure of less than 30 kPa (2 vacuuming cycles were conducted to remove oxygen from the plasma vapor deposition tube, heating was conducted at a heating rate of 12° C./min to a temperature of 850° C. under protection of the argon atmosphere at a flow rate of 20 mL/min, a plasma power was set to 200 W, and the plasma treatment was conducted for 60 min) to produce dGA.
(3) The dGA obtained in the step (2) was dried overnight for 13 h to produce dried dGA. 25 mL of pure MMEN and 20 mg of the dried dGA were added to a reactor, and heated in a forced air oven at 90° C. for 10 h. A reaction product was taken out, and an organic amine adhering to a surface of the reaction product was gently removed using an absorbent paper. A resulting sample was soaked in 170 mL of absolute ethanol at 45° C. for 20 min, and dried at 80° C. overnight for 11 h to produce an adsorption material MMEN-dGA.

MMEN loads in MMEN-dGA prepared in this example under different hydrogen treatment durations are investigated, and the maximum MMEN load is 45.0 wt %. When MMEN-dGA is used in static adsorption of CO₂ under a 100% CO₂ condition for 30 min, a CO₂ adsorption capacity reaches 5 mmol/g.

The above are only preferred examples of the present disclosure, and thus the scope of the present disclosure is not limited thereto. Equivalent changes and modifications made in accordance with the patent scope of the present disclosure and the contents of the specification shall fall within the scope of the present disclosure.

What is claimed is:

1. A preparation method of an amine-functionalized adsorption material with highly dispersed active sites, comprising following steps:
(1) placing a graphene aerogel (GA) in a tube furnace, and conducting a thermal reduction treatment to produce a thermally reduced sample;
(2) placing the thermally reduced sample obtained in the step (1) in a plasma vapor deposition tube, and subjecting the sample to a plasma treatment in different atmospheres under vacuum to produce a carrier; and
(3) drying the carrier obtained in the step (2) overnight for 8 h to 16 h; adding a polyamine organic amine and the carrier to a reactor, and heating in a forced air oven at 60° C. to 100° C. for 8 h to 15 h; taking a reaction product out, and removing an organic amine adhering to a surface of the reaction product; soaking in ethanol for 10 min to 40 min, and drying overnight for 8 h to 16 h in the forced air oven at 60° C. to 100° C. to produce the amine-functionalized adsorption material with highly dispersed active sites.

2. The preparation method according to claim 1, wherein in the step (1), the thermal reduction treatment comprises: conducting 2 to 3 vacuuming-argon purging cycles to remove oxygen from a tube, heating at a heating rate of 8° C./min to 12° C./min to a temperature of 1,200° C. to 1,600° C. under protection of argon at a flow rate of 10 mL/min to 20 mL/min, maintaining the temperature for 2 h to 3 h, and cooling naturally.

3. The preparation method according to claim 1, wherein in the step (2), the sample is subjected to the plasma treatment in different atmospheres under vacuum at an absolute pressure of less than 30 kPa.

4. The preparation method according to claim 1, wherein in the step (2), the atmosphere comprises argon, helium, hydrogen, or carbon monoxide.

5. The preparation method according to claim 1, wherein in the step (2), the plasma treatment comprises: conducting 2 to 3 vacuuming cycles to remove oxygen from the tube, heating at a heating rate of 8° C./min to 12° C./min to a temperature of 600° C. to 900° C. under protection of different atmospheres at a flow rate of 10 mL/min to 20 mL/min, setting a plasma power to 180 W to 220 W, and conducting the plasma treatment for 1 min to 180 min.

6. The preparation method according to claim 1, wherein in the step (3), the polyamino organic amine comprises triethylenetetramine (TETA), tetraethylenepentamine (TEPA), or N,N′-dimethylethylenediamine (MMEN).

7. The preparation method according to claim 1, wherein in the step (3), the drying in the oven is conducted at 60° C. to 90° C.

8. The preparation method according to claim 1, wherein in the step (3), the soaking in the ethanol is conducted at 30° C. to 50° C.
